(19) United States
(12) Patent Application Publication
(10) Pub. No.: US 2026/0004999 A1
(43) Pub. Date: Jan. 1, 2026

(54) PLASMA PROCESSING METHOD AND PLASMA PROCESSING APPARATUS FOR USING A FIRST PLASMA GENERATED FROM A FIRST PROCESSING GAS THAT INCLUDES A CARBON CONTAINING GAS IN A CHAMBER TO FORM A FIRST FILM ON AN INNNER WALL OF THE CHAMBER AND A SUBSTRATE SUPPORT SURFACE

(71) Applicant: Tokyo Electron Limited, Tokyo (JP)

(72) Inventor: Daisuke SHIRASAWA, Miyagi (JP)

(73) Assignee: Tokyo Electron Limited, Tokyo (JP)

(21) Appl. No.: 19/257,610

(22) Filed: Jul. 2, 2025

Related U.S. Application Data
(63) Continuation of application No. PCT/JP2023/047334, filed on Dec. 28, 2023.

(30) Foreign Application Priority Data
Jan. 10, 2023 (JP) 2023-001588

(51) Int. Cl. H01J 37/32

(52) U.S. Cl. CPC H01J 37/32495; H01J 37/32449; H01J 37/32862

(57) ABSTRACT

The plasma processing method includes: (a) using a first plasma generated from a first processing gas that includes a carbon containing gas in a chamber to form a first layer on an inner wall of the chamber and a substrate support surface for supporting a first substrate in the chamber, (b) placing the first substrate above the substrate support surface on which the first layer is formed, and (c) using a second plasma generated from a second processing gas different from the first processing gas when the first substrate is placed above the substrate support surface to remove the first layer formed on the inner wall of the chamber.

### CROSS-REFERENCE TO RELATED APPLICATIONS

This application is a bypass continuation application of international application No. PCT/JP2023/047334 having an international filing date of Dec. 28, 2023 and designating the United States, the international application being based upon and claiming the benefit of priority from Japanese Patent Application No. 2023-001588, filed on Jan. 10, 2023, the entire contents of each of which are incorporated herein by reference.

### TECHNICAL FIELD

Exemplary embodiments of the present disclosure relate to a plasma processing method and a plasma processing apparatus.

### BACKGROUND

PTL 1 discloses a method of forming a protective layer that protects a member in a chamber. In this method, a carbon-containing layer is formed on a surface of the member in the chamber. Next, a silicon-containing layer is formed on the formed carbon-containing layer.

### CITATION LIST

### Patent Documents

PTL 1: JP2018-133483A

### SUMMARY

The present disclosure provides a plasma processing method and a plasma processing apparatus capable of selectively forming a layer on a substrate support surface.

In one exemplary embodiment, a plasma processing method includes: (a) using a first plasma generated from a first processing gas that includes a carbon containing gas in a chamber to form a first layer on an inner wall of the chamber and a substrate support surface for supporting a first substrate in the chamber, (b) placing the first substrate above the substrate support surface on which the first layer is formed, and (c) using a second plasma generated from a second processing gas different from the first processing gas when the first substrate is placed above the substrate support surface to remove the first layer formed on the inner wall of the chamber.

According to one exemplary embodiment, the plasma processing method and a plasma processing apparatus capable of selectively forming a layer on the substrate support surface are provided.

### BRIEF DESCRIPTION OF DRAWINGS

The scope of the present disclosure is best understood from the following detailed description of exemplary embodiments when read in conjunction with the accompanying drawings.

FIG. 1 is a diagram schematically showing a plasma processing apparatus according to an exemplary embodiment.

FIG. 2 is a diagram schematically illustrating a plasma processing apparatus according to an exemplary embodiment.

FIG. 3 is a partially enlarged view of the plasma processing apparatus according to one exemplary embodiment.

FIG. 4 is a flowchart illustrating a plasma processing method according to one exemplary embodiment.

FIG. 5 is a partially enlarged view of the example plasma processing apparatus in a step of forming a first layer.

FIG. 6 is a partially enlarged view of the example plasma processing apparatus in a step of placing a first substrate.

FIG. 7 is a partially enlarged view of the example plasma processing apparatus in a step of removing the first layer.

FIG. 8 is a partially enlarged view of the example plasma processing apparatus in a step of forming a second layer.

FIG. 9 is a partially enlarged view of the example plasma processing apparatus in a step of unloading the first substrate.

FIG. 10 is a partially enlarged view of the example plasma processing apparatus in a step of placing a second substrate.

FIG. 11 is a graph illustrating an example of a relationship between temperature and torque value in fifth to eighth experiments.

### DETAILED DESCRIPTION

Hereinafter, various exemplary embodiments will be described in detail with reference to the drawings. Further, like reference numerals will be given to like or corresponding parts throughout the drawings.

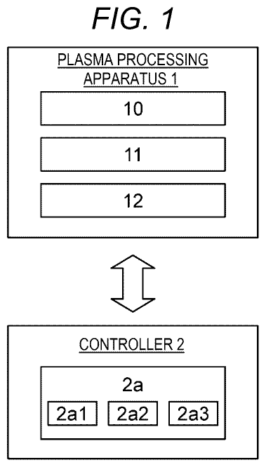

FIG. 1 is a diagram illustrating an example of a configuration of a plasma processing system. In one embodiment, the plasma processing system includes a plasma processing apparatus 1 and a controller 2 (e.g., circuitry). The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave-excited plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller/circuitry 2 processes computer-executable instructions that cause the plasma processing apparatus 1 to execute various steps described in the present disclosure. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2a1, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

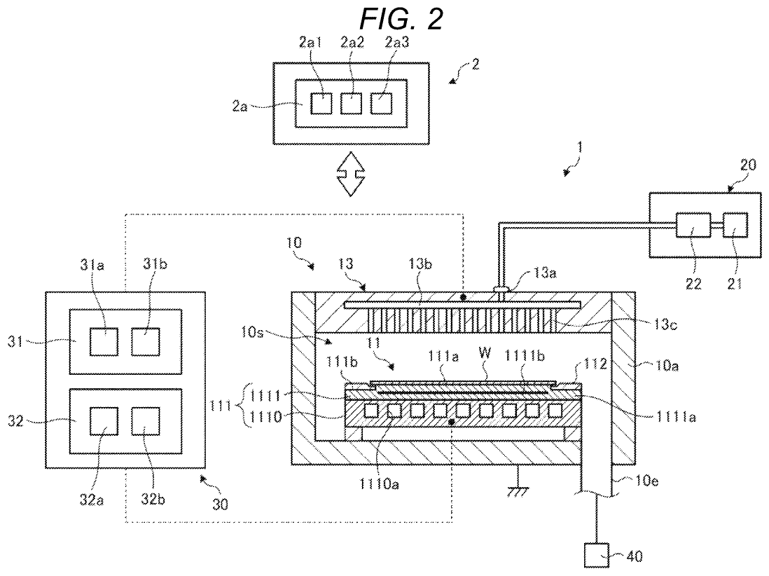

Hereinafter, an example of a configuration of a capacitively-coupled plasma processing apparatus as an example of the plasma processing apparatus 1 will be described. FIG. 2 is a diagram illustrating the example of the configuration of the capacitively-coupled plasma processing apparatus.

The capacitively-coupled plasma processing apparatus 1 includes the plasma processing chamber 10, the gas supply 20, a power source 30, and the exhaust system 40. The plasma processing apparatus 1 further includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a portion of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. At least one RF/DC electrode coupled to an RF power source 31 and/or a DC power source 32, which will be described later, may be disposed in the ceramic member 1111a. In this case, at least one RF/DC electrode functions as the lower electrode. When a bias RF signal and/or DC signal, which will be described later, are supplied to the at least one RF/DC electrode, the RF/DC electrode is also called a bias electrode. The conductive member of the base 1110 and at least one RF/DC electrode may function as a plurality of lower electrodes. The electrostatic electrode 1111b may instead function as the lower electrode. Accordingly, the substrate support 11 includes at least one lower electrode.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may further include a temperature control module configured to adjust a temperature of at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. The substrate support 11 may further include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the gas introduction ports 13c. The shower head 13 further includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Plasma is thus formed from the at least one processing gas supplied into the plasma processing space 10s. Accordingly, the RF power source 31 may function as at least a part of the plasma generator 12. Supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 10. The DC power source 32 includes a first DC generator 32a and a second DC generator 32b. In one embodiment, the first DC generator 32a is connected to at least one lower electrode to generate a first DC signal. The generated first DC signal is applied to the at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. The sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 10e disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

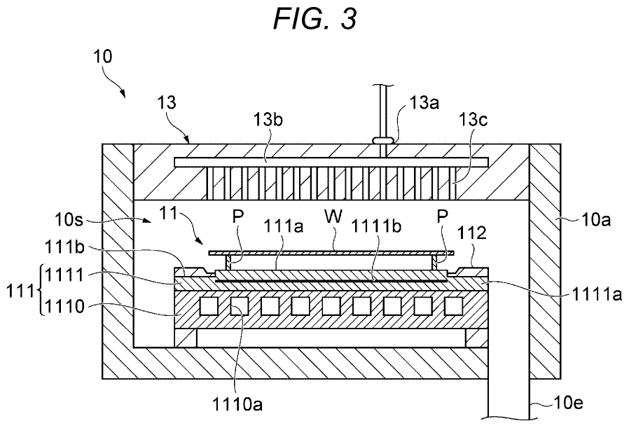

FIG. 3 is a partially enlarged view of the plasma processing apparatus according to one exemplary embodiment. As illustrated in FIG. 3, the substrate support 11 may include a pin P. The substrate support 11 may include a plurality of pins P. Each of the pins P may be raised and lowered through, for example, a through-hole formed in the central region 111a of the main body 111. The pin P may be raised and lowered by rotation of the pin P. The pin P can be raised and lowered by an elevation mechanism. The substrate W supported by tips of the pins P can be raised and lowered by raising and lowering the pins P. At a position where the pins P protrude from the central region 111a, the substrate W can be placed and unloaded by a substrate transfer device that transfers the substrate W.

As an example, the substrate W is placed on the central region 111a as follows. First, the elevation mechanism raises the pins P. Subsequently, the substrate W is placed on the tips of the pins P by the substrate transfer device when the pins P are raised. Accordingly, the substrate W is supported by the tips of the pins P. Subsequently, when the substrate W is supported by the tips of the pins P, the elevation mechanism lowers the pins P to accommodate the pins P in the main body 111. Accordingly, the substrate W is placed on the central region 111a.

As an example, the substrate W is unloaded from the plasma processing chamber 10 to an outside of the plasma processing chamber 10 as follows. First, the elevation mechanism raises the pins P when the substrate W is placed on the central region 111a. Accordingly, the substrate W is raised together with the pins P, and is supported by the tips of the pins P above the central region 111a. Subsequently, the substrate transfer device unloads the substrate W supported by the tips of the pins P to the outside of the plasma processing chamber 10. Subsequently, the elevation mechanism lowers the pins P to accommodate the pins P in the main body 111. Accordingly, the substrate W is unloaded from the plasma processing chamber 10.

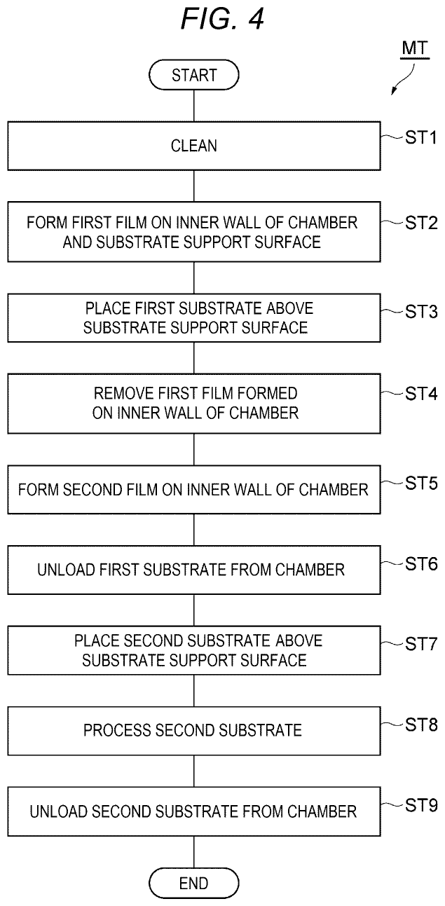

FIG. 4 is a flowchart illustrating a plasma processing method according to one exemplary embodiment. The plasma processing method illustrated in FIG. 4 (hereinafter referred to as a “method MT”) may be executed by the plasma processing apparatus 1 in the embodiment. The method MT may be applied to a substrate W. In one embodiment, the substrate W may be a first substrate W1. The first substrate W1 may be a dummy substrate. The substrate W may be a second substrate W2 different from the first substrate W1. The second substrate W2 may be a substrate that contains a pattern for an integrated circuit. Therefore, the method MT may be applied to the first substrate W1 and the second substrate W2 as well. The method MT may include step ST1 to step ST9. Step ST1 to step ST9 may be performed sequentially. The method MT may not include step ST1. The method MT does not necessarily include at least one of steps ST5 to ST9. Hereinafter, the method MT will be described with reference to FIGS. 4 to 10.

### Step ST1

In step ST1, the plasma processing chamber 10 is cleaned. In step ST1, a cleaning gas may be used. The cleaning gas may contain fluorine, chlorine, or oxygen.

### Step ST2

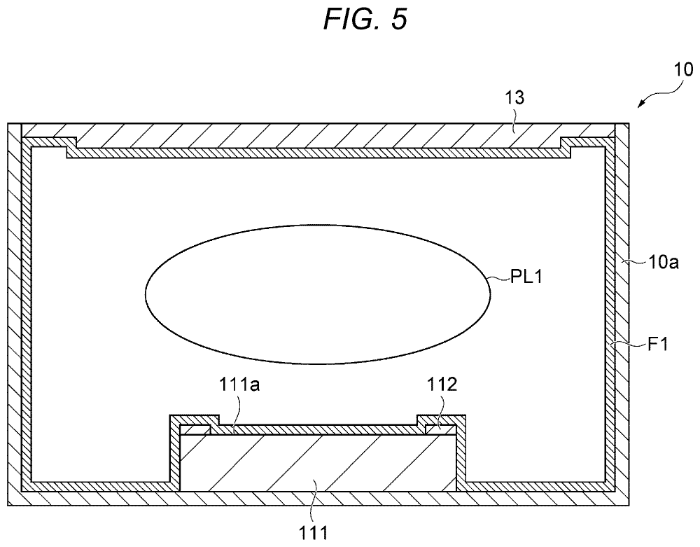

FIG. 5 is a partially enlarged view of the example plasma processing apparatus in a step of forming a first layer. In step ST2, a first layer F1 is formed on an inner wall of the plasma processing chamber 10 and the central region 111a (substrate support surface) using a first plasma PL1 generated from a first processing gas that includes a carbon containing gas within the plasma processing chamber 10. The first layer F1 may be conductive. As an example, the first layer F1 may be formed while an object (e.g., the substrate W) that covers the central region 111a is not placed on the central region 111a. The first layer F1 may cover the inner wall of the plasma processing chamber 10, the central region 111a, a sidewall of the main body 111, the ring assembly 112, and the shower head 13. The first layer F1 contains carbon. The first layer F1 may be a carbon layer. The first layer F1 may be a diamond-like carbon layer. The first layer F1 may have a thickness of 10 nm or more and 50 nm or less. In FIGS. 5 to 10, the thickness of the first layer F1 is illustrated to be different from an actual thickness of the first layer F1 in order to clarify a position where the first layer F1 is formed.

The first processing gas includes the carbon containing gas. The first processing gas may not contain halogen. The carbon containing gas included in the first processing gas may include a CₓH_{y}O_{z} gas. Here, x is an integer of 1 or more, y is an integer of 1 or more, and z is an integer of 0 or more. CₓH_{y}O_{z} gas may include at least one type selected from the group consisting of a CH₄ gas, a C₂H₂ gas, a CH₄O gas, a C₂H₆O gas, a C₃H₈ gas, a C₄H₁₀ gas, a C₇H₈ gas, and a C₆H₆ gas. The first processing gas may further include a hydrogen containing gas. Examples of the hydrogen-containing gas include a hydrogen gas. The first processing gas may further include a nitrogen containing gas. Examples of the nitrogen containing gas include a nitrogen gas. The first processing gas may further include a noble gas. Examples of the noble gas include a helium gas, an argon gas, a neon gas, a xenon gas, and a krypton gas. At the end of step ST2, supply of the first processing gas may be stopped.

### Step ST3

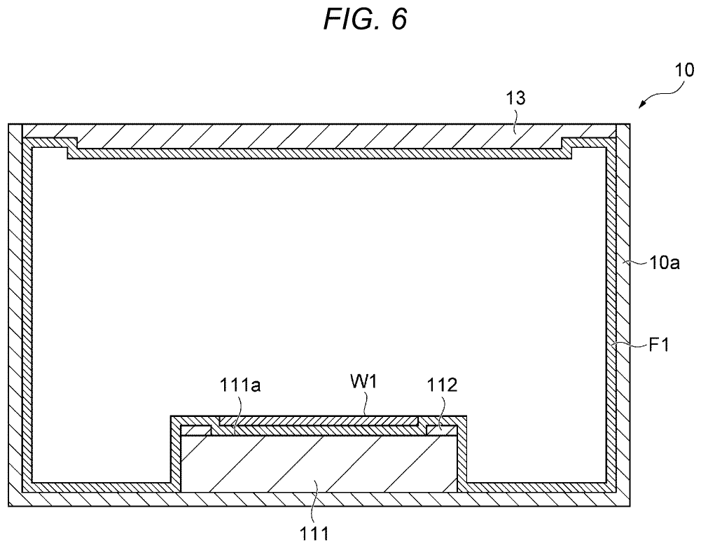

FIG. 6 is a partially enlarged view of the example plasma processing apparatus in a step of placing the first substrate. In step ST3, the first substrate W1 is placed above the central region 111a where the first layer F1 is formed. The first substrate W1 may be placed above the central region 111a to cover the first layer F1. The first layer F1 may be disposed between the central region 111a and the first substrate W1. The first substrate W1 may be in contact with the first layer F1. The first substrate W1 may be placed above the central region 111a by the substrate transfer device described above.

### Step ST4

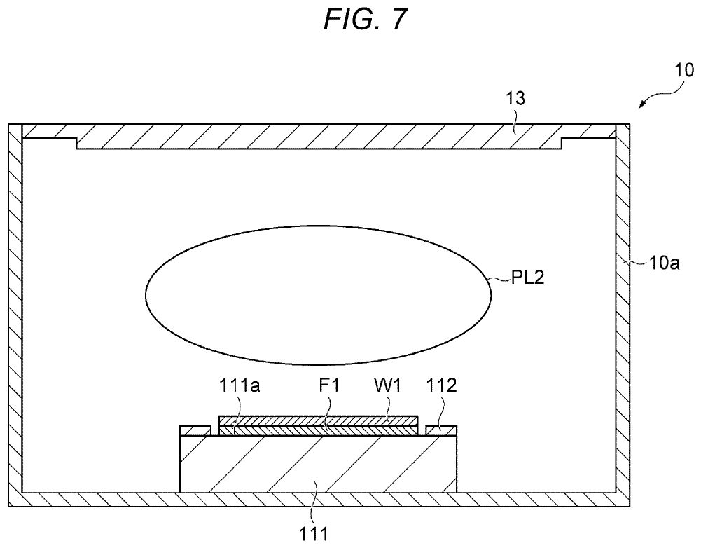

FIG. 7 is a partially enlarged view of the example plasma processing apparatus in a step of removing the first layer. In step ST4, the first layer F1 formed on the inner wall of the plasma processing chamber 10 is removed using a second plasma PL2 generated from a second processing gas different from the first processing gas when the first substrate W1 is placed above the central region 111a. Since the first substrate W1 is placed above the central region 111a, the other first layers F1 may be removed while the first layer F1 between the first substrate W1 and the central region 111a remains. Accordingly, the first layer F1 formed on the inner wall of the plasma processing chamber 10 may be removed. In step ST4, a temperature of the inner wall of the plasma processing chamber 10 may be 20° C. or higher and 300° C. or lower.

The second processing gas may contain at least one of an oxygen containing gas or a fluorine containing gas. The oxygen containing gas may contain at least one type selected from the group consisting of an O₂ gas, an O₃ gas, a CO gas, and a CO₂ gas. The fluorine containing gas may contain at least one type selected from the group consisting of a CF₄ gas, an NF₃ gas, and an SF₆ gas. The second processing gas may further include a noble gas. At the end of step ST4, supply of the second processing gas may be stopped.

### Step ST5

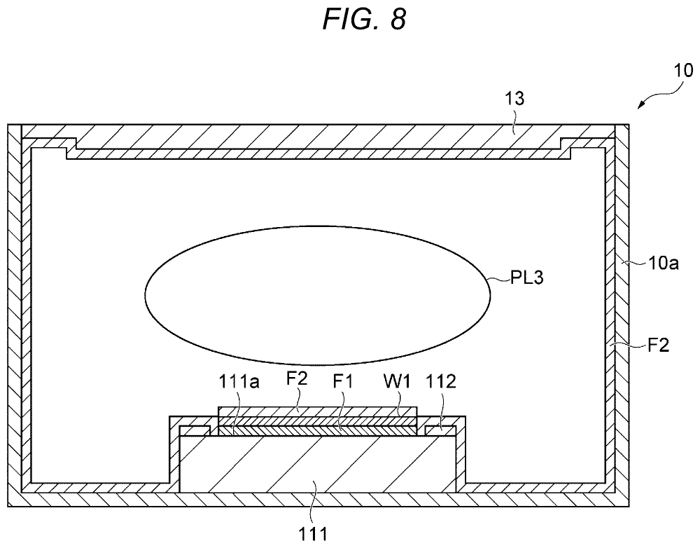

FIG. 8 is a partially enlarged view of the example plasma processing apparatus in a step of forming a second layer. In step ST5, the second layer F2 is formed on the inner wall of the plasma processing chamber 10 using a third plasma PL3 generated from a third processing gas different from the first processing gas and the second processing gas when the first substrate W1 is placed above the central region 111a. The second layer F2 may cover the inner wall of the plasma processing chamber 10, the sidewall of the main body 111, the ring assembly 112, the shower head 13, and the first substrate W1. The second layer F2 may be formed in a state where the first layer F1 is disposed between the first substrate W1 and the central region 111a. The second layer F2 may contain at least one of silicon or a metal. The second layer F2 may contain a silicon oxide. The second layer F2 may be a silicon oxide layer. The second layer F2 may contain a metal oxide. The second layer F2 may be a metal oxide layer. In FIGS. 8 to 10, a thickness of the second layer F2 is illustrated to be different from an actual thickness of the second layer F2 in order to clarify a position where the second layer F2 is formed.

The third processing gas may include at least one of a silicon containing gas or a metal containing gas. The silicon containing gas may contain at least one type selected from the group consisting of a SiCl₄ gas, a SiH₄ gas, a SiH(OR)₃ gas, a SiF₄ gas, a Si₂F₆ gas, a Si₂H₆ gas, and a Si₃H₈ gas. In the SiH(OR)₃ gas, R represents a hydrocarbon group. The metal containing gas may contain at least one type selected from the group consisting of titanium, tungsten, and tantalum. The metal containing gas may contain at least one type selected from the group consisting of a TiCl₄ gas, a WF₆ gas, and a TaF₅ gas. The third processing gas may further include an oxygen-containing gas. Examples of the oxygen-containing gas include an oxygen gas. The third processing gas may further include a noble gas. The third processing gas may further include a hydrogen containing gas. Examples of the hydrogen-containing gas include a hydrogen gas. The third processing gas may further include a nitrogen containing gas. Examples of the nitrogen containing gas include a nitrogen gas. At the end of step ST5, supply of the third processing gas may be stopped.

### Step ST6

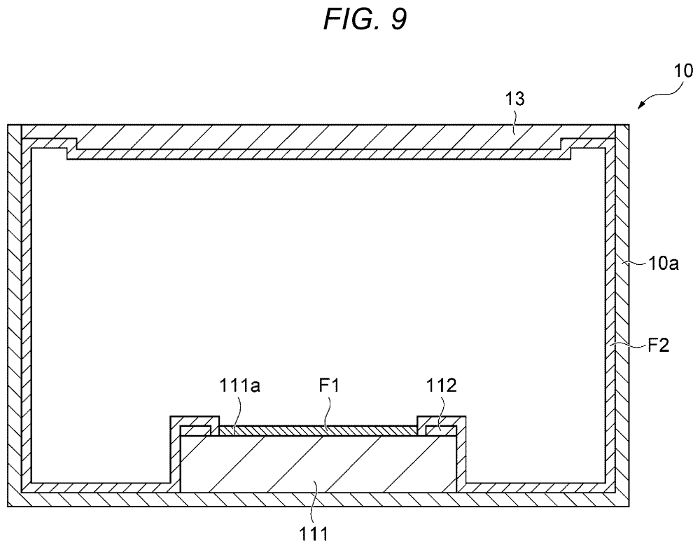

FIG. 9 is a partially enlarged view of the example plasma processing apparatus in a step of unloading the first substrate. In step ST6, the first substrate W1 is unloaded from the plasma processing chamber 10. The first substrate W1 may be unloaded from the plasma processing chamber 10 by the substrate transfer device described above.

### Step ST7

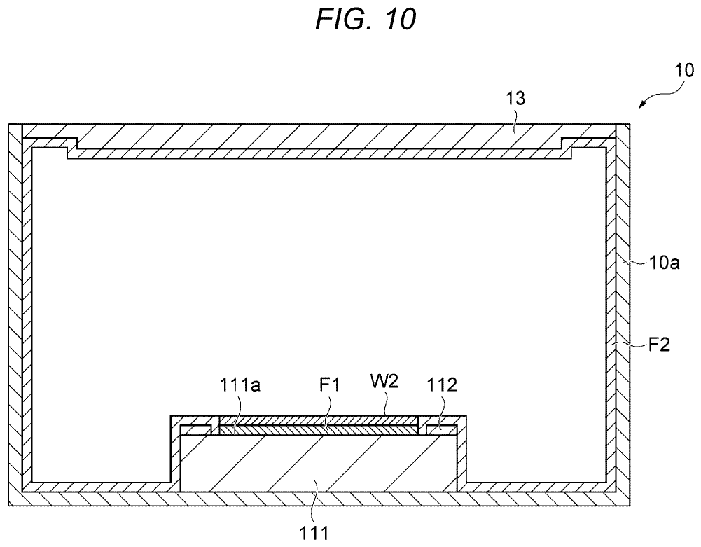

FIG. 10 is a partially enlarged view of the example plasma processing apparatus in a step of placing the second substrate. In step ST7, the second substrate W2 different from the first substrate W1 is placed above the central region 111a. The second substrate W2 may be placed above the central region 111a by the substrate transfer device described above.

### Step ST8

In step ST8, the second substrate W2 is processed in the plasma processing chamber 10. The second substrate W2 may be processed with a plasma generated from a processing gas different from the first processing gas, the second processing gas, and the third processing gas. In step ST8, the second substrate W2 may be etched. Accordingly, a recess may be formed in the second substrate W2.

### Step ST9

In step ST9, the second substrate W2 is unloaded from the plasma processing chamber 10. The second substrate W2 may be unloaded from the plasma processing chamber 10 by the substrate transfer device described above.

According to the plasma processing apparatus 1 and the method MT described above, the first layer F1 can be selectively formed on the central region 111a that is the substrate support surface. Further, the first layer F1 containing at least carbon is formed on the central region 111a that is the substrate support surface. When the first layer F1 contains carbon, it is possible to prevent generation of particles that may occur due to friction between the first layer F1 and the substrate W. The friction between the first layer F1 and the substrate W may occur due to thermal expansion or contraction of the first layer F1 and the substrate W due to a temperature change. When the first layer F1 contains carbon, a degree of adsorption between the substrate W and the central region 111a can be reduced in a high temperature region (for example, 100° C. or higher). For example, a torque value of the pin P (see FIG. 3) when the substrate W is raised and lowered by rotation of the pin P can be reduced. The torque value is an index indicating the degree of adsorption between the substrate W and the central region 111a. As an example, the torque value indicates a voltage required for raising the pin P by the elevation mechanism when the substrate W is placed on the central region 111a. A large torque value indicates a high degree of adsorption between the substrate W and the central region 111a. When the first layer F1 is conductive, charges in the central region 111a flow through the first layer F1, so that charges of the central region 111a are unlikely to accumulate. When it is difficult for charges to accumulate in the central region 111a, the degree of adsorption between the substrate W and the central region 111a decreases. Therefore, it is presumed that the torque value of the pin P is reduced.

Through step ST5 and step ST6, the second layer F2 can be selectively formed on the inner wall of the plasma processing chamber 10, the sidewall of the main body 111, the ring assembly 112, and the shower head 13. When the second layer F2 contains a silicon oxide, the second layer F2 is unlikely to be damaged even if a plasma containing oxygen is formed in the plasma processing chamber 10. Therefore, the inner wall of the plasma processing chamber 10 and parts in the plasma processing chamber 10 can be protected.

When the first layer F1 has a thickness of 10 nm or more, generation of particles can be further reduced, and the torque value of the pin P may be further reduced. When the first layer F1 has a thickness of 50 nm or less, peeling of the first layer F1 from the central region 111a can be prevented.

Hereinafter, various experiments performed to evaluate the method MT will be described. The following experiments are not intended to limit the present disclosure.

### First Experiment

In the first experiment, a carbon layer was formed on the substrate support surface by a plasma generated from a processing gas that includes a CH₄ gas. Thereafter, with the carbon layer formed on the substrate support surface, a substrate was placed above the substrate support surface. Thereafter, the substrate was heated under a first temperature condition or a second temperature condition. Under the first temperature condition, a temperature of the substrate was maintained at 40° C. for 20 seconds. Under the second temperature condition, the temperature of the substrate was maintained at 60° C. for about 10 seconds (for example, for 10 seconds, between 9-11 seconds, etc.), then changed from 60° C. to 40° C., and then maintained at 40° C. for about 10 seconds (for example, for 10 seconds, between 9-11 seconds, etc.).

### Second Experiment

The second experiment was performed in the same manner as in the first experiment except that a pressure at the time of forming the carbon layer was changed.

### Third Experiment

The third experiment was performed in the same manner as in the first experiment except that no carbon layer was formed. Therefore, the substrate was placed on the substrate support surface in contact with the substrate support surface.

### Fourth Experiment

A fourth experiment was performed in the same manner as the first experiment except that a silicon oxide layer was formed on the substrate support surface instead of the carbon layer.

### First Experiment Result

In the first to fourth experiments, the number of particles that adhered to the substrate was counted. Here, the first to fourth experiments were each performed three times, and an average value of the number of particles counted was calculated. In the following description, E1a, E2a, E3a, and E4a are described as the number of particles when a temperature condition is the first temperature condition in the first to fourth experiments, respectively. Similarly, in the following description, E1b, E2b, E3b, and E4b are described as the number of particles when the temperature condition is the second temperature condition in the first to fourth experiments, respectively.

In the first experiment, E1a was 5.5, and E1b was 6.0. In the second experiment, E2a was 6.0, and E2b was 7.3. In the third experiment, E3a was 4.0, and E3b was 17.0. In the fourth experiment, E4a was 4.0, and E4b was 11.7. First, comparing E1a to E4a when the temperature condition is set to the first temperature condition, the number of particles is stable at a small value in the first to fourth experiments. In contrast, comparing E1b to E4b when the temperature condition is set to the second temperature condition, it can be seen that the number of particles in the first experiment and the second experiment is smaller than that in the third experiment and the fourth experiment. Therefore, it is understood that in the first experiment and the second experiment, the number of particles that adhere to the substrate can be reduced.

### Fifth Experiment

In the fifth experiment, as in the first experiment, a carbon layer was formed on the substrate support surface. Thereafter, with the carbon layer formed on the substrate support surface, a substrate was placed above the substrate support surface. Thereafter, at 40° C., 80° C., or 120° C., the substrate was raised by rotating the pins.

### Sixth Experiment

The sixth experiment was performed in the same manner as in the fifth experiment except that a pressure at the time of forming the carbon layer was changed.

### Seventh Experiment

The seventh experiment was performed in the same manner as in the fifth experiment except that no carbon layer was formed. Therefore, the substrate was placed on the substrate support surface in contact with the substrate support surface.

### Eighth Experiment

The eighth experiment was performed in the same manner as the fifth experiment except that a silicon oxide layer was formed on the substrate support surface instead of the carbon layer.

### Second Experiment Result

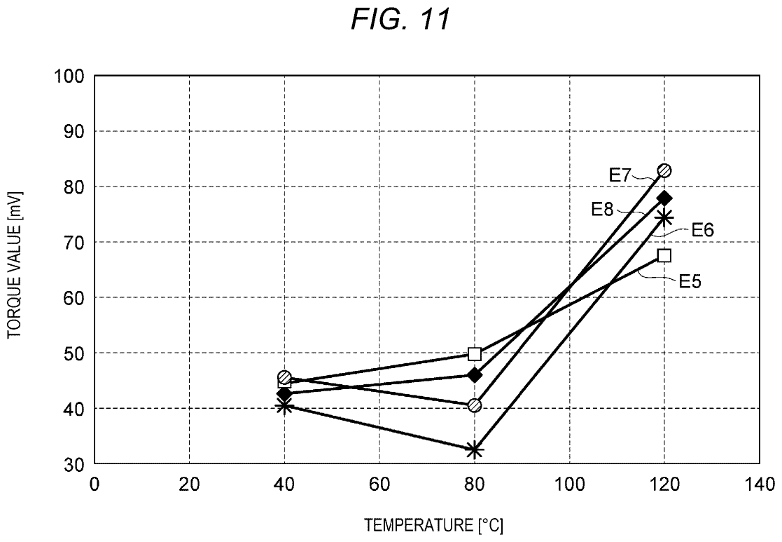

In the fifth to eighth experiments, a torque value was measured when the pin rotated. FIG. 11 is a graph illustrating an example of a relationship between temperature and torque value in fifth to eighth experiments. A horizontal axis of the graph represents the temperature (° C.) of the substrate. A vertical axis of the graph represents the torque value (mV). The torque value is a drive voltage for rotating the pin. In the graph, E5 to E8 represent results of the fifth to eighth experiments, respectively. As illustrated in FIG. 11, when the substrate was raised by the rotation of the pin at 120° C., the torque values in the fifth experiment and sixth experiment were smaller than those in the seventh experiment and eighth experiment.

While various exemplary embodiments have been described above, various additions, omissions, substitutions and changes may be made without being limited to the exemplary embodiments described above. Also, the other embodiments may be formed by combining elements in different embodiments.

Hereinafter, various exemplary embodiments included in the present disclosure will be described in [E1] to [E16].

### [E1]

A plasma processing method including:
(a) using a first plasma generated from a first processing gas that includes a carbon containing gas in a chamber to form a first layer on an inner wall of the chamber and a substrate support surface for supporting a first substrate in the chamber,
(b) placing the first substrate above the substrate support surface on which the first layer is formed, and
(c) using a second plasma generated from a second processing gas different from the first processing gas when the first substrate is placed above the substrate support surface to remove the first layer formed on the inner wall of the chamber.

According to the plasma processing method [E1], the first layer can be selectively formed on the substrate support surface.

### [E2]

The plasma processing method according to [E1], in which the first layer is conductive.

### [E3]

The plasma processing method according to [E1] or [E2], further including:
(d) after (c), using a third plasma generated from a third processing gas different from the first processing gas and the second processing gas when the first substrate is placed above the substrate support surface to form a second layer on the inner wall of the chamber.

### [E4]

The plasma processing method according to [E3], further including:
(e) after (d), unloading the first substrate from the chamber.

### [E5]

The plasma processing method according to [E4], further including:
(f) after (e), placing a second substrate different from the first substrate above the substrate support surface.

### [E6]

The plasma processing method according to any one of [E1] to [E5], in which the carbon containing gas includes a CₓH_{y}O_{z} gas, x is an integer of 1 or more, y is an integer of 1 or more, and z is an integer of 0 or more.

### [E7]

The plasma processing method according to [E6], in which the CₓH_{y}O_{z} gas includes at least one type selected from the group consisting of a CH₄ gas, a C₂H₂ gas, a CH₄O gas, a C₂H₆O gas, a C₃H₈ gas, a C₄H₁₀ gas, a C₇H₈ gas, and a C₆H₆ gas.

### [E8]

The plasma processing method according to any one of [E1] to [E7], in which the second processing gas includes at least one of an oxygen containing gas or a fluorine containing gas.

### [E9]

The plasma processing method according to [E8], in which the oxygen containing gas includes at least one type selected from the group consisting of an O₂ gas, an O₃ gas, a CO gas, and a CO₂ gas.

### [E10]

The plasma processing method according to [E8], in which the fluorine containing gas includes at least one type selected from the group consisting of a CF₄ gas, an NF₃ gas, and an SF₆ gas.

### [E11]

The plasma processing method according to any one of [E3] to [E5], in which the third processing gas includes at least one of a silicon containing gas or a metal containing gas.

### [E12]

The plasma processing method according to [E11], in which the silicon containing gas includes at least one type selected from the group consisting of a SiCl₄ gas, a SiH₄ gas, a SiH(OR)₃ gas, a SiF₄ gas, a Si₂F₆ gas, a Si₂H₆ gas, and a Si₃H₈ gas, in the SiH(OR)₃ gas, R representing a hydrocarbon group.

### [E13]

The plasma processing method according to [E11], in which the metal containing gas contains at least one type selected from the group consisting of titanium, tungsten, and tantalum.

### [E14]

The plasma processing method according to [E13], in which the metal containing gas includes at least one type selected from the group consisting of a TiCl₄ gas, a WF₆ gas, and a TaF₅ gas.

### [E15]

The plasma processing method according to any one of [E1] to [E14], in which the first layer has a thickness of 10 nm or more and 50 nm or less.

### [E16]

A plasma processing apparatus including:
a chamber,
a substrate support having a substrate support surface for supporting a substrate in the chamber,
a gas supply configured to supply a first processing gas and a second processing gas different from the first processing gas into the chamber, the first processing gas including a carbon containing gas,
a plasma generator configured to generate a first plasma and a second plasma from the first processing gas and the second processing gas, respectively, in the chamber, and
a controller configured to control the gas supply and the plasma generator to use the first plasma to form a first layer on an inner wall of the chamber and the substrate support surface, and to use the second plasma when the substrate is placed on the substrate support surface to remove the first layer formed on the inner wall of the chamber.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112 (f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. A plasma processing method comprising:
(a) using a first plasma generated from a first processing gas that includes a carbon containing gas in a chamber to form a first layer on an inner wall of the chamber and a substrate support surface for supporting a first substrate in the chamber,
(b) placing the first substrate above the substrate support surface on which the first layer is formed, and
(c) using a second plasma generated from a second processing gas different from the first processing gas when the first substrate is placed above the substrate support surface to remove the first layer formed on the inner wall of the chamber.

2. The plasma processing method according to claim 1, wherein
the first layer is conductive.

3. The plasma processing method according to claim 1, further comprising:
(d) after (c), using a third plasma generated from a third processing gas different from the first processing gas and the second processing gas when the first substrate is placed above the substrate support surface to form a second layer on the inner wall of the chamber.

4. The plasma processing method according to claim 3, further comprising:
(e) after (d), unloading the first substrate from the chamber.

5. The plasma processing method according to claim 4, further comprising:
(f) after (e), placing a second substrate different from the first substrate above the substrate support surface.

6. The plasma processing method according to claim 1, wherein
the carbon containing gas includes a CₓH_{y}O_{z} gas, where x is an integer of 1 or more, y is an integer of 1 or more, and z is an integer of 0 or more.

7. The plasma processing method according to claim 6, wherein
the CₓH_{y}O_{z} gas includes at least one type selected from a group consisting of a CH₄ gas, a C₂H₂ gas, a CH₄O gas, a C₂H₆₀ gas, a C₃H₈ gas, a C₄H₁₀ gas, a C₇H₂ gas, and a C₆H₆ gas.

8. The plasma processing method according to claim 1, wherein
the second processing gas includes at least one of an oxygen containing gas or a fluorine containing gas.

9. The plasma processing method according to claim 8, wherein
the oxygen containing gas includes at least one type selected from a group consisting of an O₂ gas, an O₃ gas, a CO gas, and a CO₂ gas.

10. The plasma processing method according to claim 8, wherein
the fluorine containing gas includes at least one type selected from a group consisting of a CF₄ gas, an NF₃ gas, and an SF₆ gas.

11. The plasma processing method according to claim 3, wherein
the third processing gas includes at least one of a silicon containing gas or a metal containing gas.

12. The plasma processing method according to claim 11, wherein
the silicon containing gas includes at least one type selected from a group consisting of a SiCl₄ gas, a SiH₄ gas, a SiH(OR)₃ gas, a SiF₄ gas, a Si₂F₆ gas, a Si₂H₆ gas, and a Si₃H₈ gas,
in the SiH(OR)₃ gas, R represents a hydrocarbon group.

13. The plasma processing method according to claim 11, wherein
the metal containing gas contains at least one type selected from a group consisting of titanium, tungsten, and tantalum.

14. The plasma processing method according to claim 13, wherein
the metal containing gas includes at least one type selected from a group consisting of a TiCl₄ gas, a WF₆ gas, and a TaF₅ gas.

15. The plasma processing method according to claim 1, wherein
the first layer has a thickness of 10 nm or more and 50 nm or less.

16. A plasma processing apparatus comprising:
a chamber,
a substrate support having a substrate support surface for supporting a substrate in the chamber,
a gas supply configured to supply a first processing gas and a second processing gas different from the first processing gas into the chamber, the first processing gas including a carbon containing gas,
a plasma generator configured to generate a first plasma and a second plasma from the first processing gas and the second processing gas, respectively, in the chamber, and
circuitry configured to control the gas supply and the plasma generator to use the first plasma to form a first layer on an inner wall of the chamber and the substrate support surface, and to use the second plasma when the substrate is placed on the substrate support surface to remove the first layer formed on the inner wall of the chamber.

17. The plasma processing method according to claim 2, wherein
the carbon containing gas includes a CₓH_{y}O_{z} gas, where x is an integer of 1 or more, y is an integer of 1 or more, and z is an integer of 0 or more.

18. The plasma processing method according to claim 3, wherein
the carbon containing gas includes a CₓH_{y}O_{z} gas, where x is an integer of 1 or more, y is an integer of 1 or more, and z is an integer of 0 or more.

19. The plasma processing method according to claim 4, wherein
the carbon containing gas includes a CₓH_{y}O_{z} gas, where x is an integer of 1 or more, y is an integer of 1 or more, and z is an integer of 0 or more.

20. The plasma processing method according to claim 5, wherein
the carbon containing gas includes a CₓH_{y}O_{z} gas, where x is an integer of 1 or more, y is an integer of 1 or more, and z is an integer of 0 or more.
